(19) United States
(12) Patent Application Publication
(10) Pub. No.: US 2005/0141266 A1
(43) Pub. Date: Jun. 30, 2005

(54) Semiconductor device

(75) Inventor: Jin Hyo Jung, Bucheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DongbuAnam Semiconductor Inc.

(21) Appl. No.: 11/022,684

(22) Filed: Dec. 28, 2004

(30) Foreign Application Priority Data
Dec. 31, 2003 (KR) 10-2003-0101079

(51) Int. Cl. G11C 11/00

(52) U.S. Cl. 365/154

(57) ABSTRACT

An nvSRAM having a stacked oxide layer is disclosed. A disclosed device comprises: two NMOS transistors and two PMOS transistors for an SRAM latch; two NMOS pass gates for reading and writing a HIGH condition and a LOW condition that are formed in the SRAM latch; and two floating gate NVM devices of split gate structure for storing the HIGH condition and the LOW condition that are stored in the SRAM latch when the power is off.

### BACKGROUND OF THE INVENTION

1. Field of the Invention

The present invention relates to a nonvolatile static random access memory (hereinafter referred to as “nvSRAM”), more particularly, an nvSRAM having a stacked oxide layer instead of conventional silicon-oxide-nitride-oxide-silicon(hereinafter referred to as “SONOS”) structure.

2. Background of the Related Art

FIG. 1 is a cross-sectional view illustrating structure of an nvSRAM unit cell using a SONOS device in accordance with the prior art.

The unit cell of the conventional nvSRAM comprises eight negative-channel metal oxide semiconductor(hereinafter referred to as “NMOS”) transistors, two positive-channel metal oxide semiconductor(hereinafter referred to as “PMOS”) transistors and two SONOS transistors. In detail, two NMOS transistors and two PMOS transistors for an SRAM latch, two NMOS pass gates for reading and writing a HIGH condition and a LOW condition that are formed in the SRAM latch, two SONOS transistors for storing the HIGH condition and the LOW condition which are stored in the SRAM latch when the power is off, two NMOS pass gates and two NMOS recall gates as a tri-gate for controlling a read operation, a write operation and an erase operation of the SONOS transistors.

The operation principles of the conventional nvSRAM using SONOS devices are as follows. First, while a system operates, the tri-gate is turned off by applying 0[V] to a Vrcl, a Vpas and a Vse and the, SONOS transistors are isolated from the SRAM latch so that the SONOS transistors are not affected by the state of the SRAM latch. If the system is turned off, the state of the SRAM latch is stored in each SONOS transistor, undergoing an erase mode and a program mode one by one.

First, in the erase mode, a negative voltage between −10[V] and −15[V], which can be varied on the various factors such as an erase speed, an erase time and oxide-nitride-oxide(hereinafter referred to as “ONO”) stack structure, is applied to an SONOS gate. 0[V] is applied to the Vrcl and the Vpas for a predetermined time. The bias voltage is generally applied for less than 10[msec].

Under such a bias condition of the erase mode, the recall gate and the pass gate lie in an OFF state and the SONOS transistor experiences a transition to the store mode. Most of the electric field, caused by the voltage applied to the SONOS gate, is centralized in the ONO layer. Due to the strong electric field applied to the ONO layer, the holes accumulated on the silicon substrate where the SONOS gate is located move through the tunnel oxide layer of the SONOS gate by tunneling mechanism and get entrapped in traps within a nitride layer, or the electrons trapped within the nitride layer escape through the tunnel oxide layer to the silicon substrate. Therefore, the threshold voltage decreases, so that the SONOS transistor reaches an erase state.

In the program mode, a positive voltage between +10[V] and +15[V], which can be varied on the various factors such as a program speed, a program time, ONO stack structure and dynamic write inhibition(hereinafter referred to as “DWI”), is applied to the SONOS gate while 0[V] and “H”, which means a HIGH condition or a voltage, generally 2.5[V], for recognizing the HIGH conduction, are applied to the Vrcl and the Vpas respectively for a predetermined time. The bias voltage is generally applied for less than 10[msec].

Under such a bias condition of the program mode, the recall gate lies in an OFF state and a Vcc voltage affects nothing. The ON state of the pass gate get influenced by the HIGH condition and the LOW condition stored in the SRAM latch. Referring to FIG. 1, if the HIGH condition and the LOW condition are stored in the left side and the right side of the SRAM latch respectively, the voltage difference between the gate and the source of the pass gate connected to “H” becomes close to 0[V] which means an OFF state, so that the silicon substrate under the SONOS gate enters into a deep depletion state due to the positive voltage applied to the SONOS gate. Therefore, in this deep depletion state, since the electric field by the positive voltage applied to the SONOS gate mostly exists in a deep depletion region and is hardly applied to the ONO layer, the program operation, during which electrons are trapped in the nitride layer by passing through the tunnel oxide layer, does not take place. This case is called DWI. The deep depletion normally occurs in a non-equilibrium state. Therefore, if an equilibrium state is reached as time elapses, no more DWI is likely to happen. Namely, at the beginning of the program mode, the program operation cannot be normally conducted due to the DWI. However, the DWI disappears after a certain time, so that the program operation is properly carried out. Although the characteristic of the DWI depends on a device structure, the DWI generally lasts for 1[msec] to 10[msec].

In the meantime, the voltage difference between the gate and the source of the pass gate connected to “L” becomes “H”[V] which means an ON state, so that the silicon substrate under the SONOS gate almost reaches “L”[V](generally close to 0[V]). Since the voltage for program operation applied to the SONOS gate is mostly applied to the ONO layer, the program operation, during which electrons accumulated on the silicon substrate are trapped in the nitride layer by passing through the tunnel oxide layer, takes place. Therefore, the trapped electrons increase the threshold voltage of the SONOS transistor.

As a result, during the program mode, the SONOS transistor connected to “H” is inhibited from performing the program operation due to the DWI, thereby keeps its initial erase state and has a low threshold voltage. On the contrary, the SONOS transistor connected to “L” carries out the program operation, so that it has a high threshold voltage.

When the system power is turned on, a recall operation that calls data stored in the SONOS device is carried out. During the recall operation, 0[V] is applied to the Vse and “H” is applied to the Vrcl and the Vpas.

Under such a bias condition of the recall operation, as the recall gate and the pass gate as well as the erased SONOS device in left side become an ON state, a current flows, so that the left side of the SRAM latch becomes a HIGH condition. Meanwhile, the programmed SONOS device in the right side becomes an OFF state, so that a current does not flow and the right side of the SRAM latch lies in a LOW condition.

Therefore, even if the system is turned off undergoing the erase operation, the program operation and the recall operation, the data stored in the SRAM can be safely retained.

Since the conventional nvSRAM using the SONOS device which operates in two modes, one for the program operation and another for the DWI according to the state of the SRAM latch, selectively carries out the program operation to store data, a DWI characteristic as well as the speed of the program operation are required to be improved. However, the improvement of the DWI characteristic is very difficult. Although the program operation time is increased, the threshold voltage window, which means the difference between the threshold voltages of the program operation and the DWI, cannot be increased over a certain value due to DWI mechanism.

In addition, the thickness of the tunnel oxide layer of the SONOS transistor is very thin(generally 20 Å or so), so that a characteristic of the retention is very worse. If the program speed of the SONOS device is relatively slow, so that the system enters into an OFF state, a quite large capacitor is required to keep a certain voltage for storing data that exists in the SRAM latch for a certain time.

### SUMMARY OF THE INVENTION

Accordingly, the present invention is directed to an nvSRAM that substantially obviates one or more problems due to limitations and disadvantages of the related art.

An object of the present invention is to provide a new type of an nvSRAM having a stacked oxide layer.

To achieve these objects and other advantages and in accordance with the purpose of the invention, as embodied and broadly described herein, a semiconductor device comprises: two NMOS transistors and two PMOS transistors for a SRAM latch; two NMOS pass gates for reading and writing a HIGH condition and a LOW condition that are formed in the SRAM latch; and two floating gate NVM devices of split gate structure for storing the HIGH condition and the LOW condition that are stored in the SRAM latch when the power is off.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings;

FIG. 1 is a cross-sectional view illustrating structure of an nvSRAM unit cell using an SONOS device in accordance with the prior art;

FIG. 2 is a cross-sectional view illustrating a floating gate nonvolatile memory(hereinafter referred to as “NVM”) device of split gate structure in accordance with the present invention;

FIG. 3 is a circuit illustrating nvSRAM structure using a floating gate NVM device in accordance with the present invention;

FIG. 4 is a circuit illustrating a static current pass which occurs in the program mode;

FIG. 5 is a cross-sectional view illustrating a floating gate NVM device of split gate structure in accordance with the present invention.

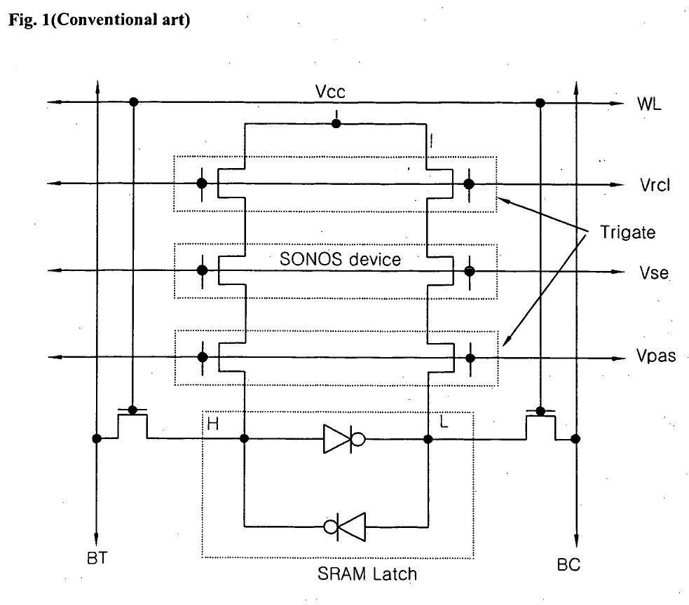

### DETAILED DESCRIPTION OF THE PREFERRED EMBODIMENT

Reference will now be made in detail to the preferred embodiments of the present invention, examples of which are illustrated in the accompanying drawings.

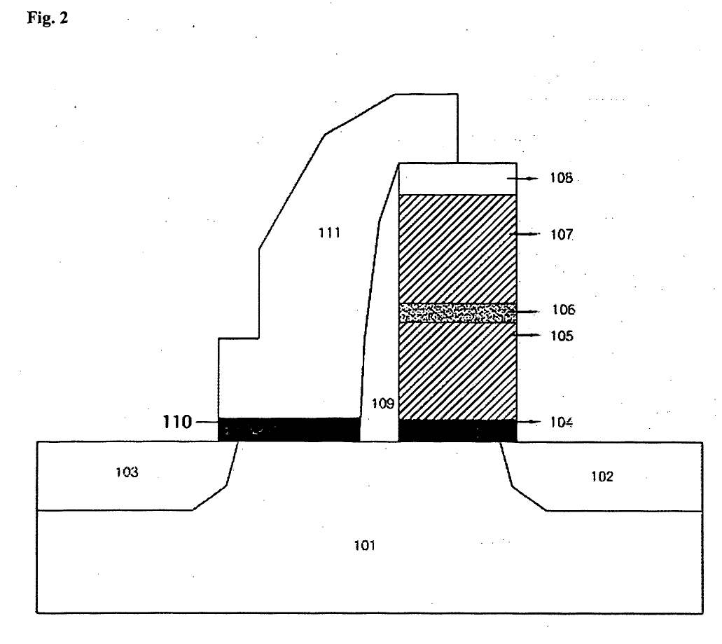

FIG. 2 is a cross-sectional view illustrating a floating gate NVM device of a split gate structure according to the present invention.

Referring to FIG. 2, SiO₂ is grown on a P-type silicon substrate 101, so that a tunnel oxide layer 104 is completed. A polysilicon floating gate 105, an ONO layer 106 and a control gate 107 are sequentially positioned on the tunnel oxide layer 104. A split gate 111 is located next to a floating gate NVM and a split gate oxide layer 110 is positioned between the split gate 111 and the silicon substrate 101. The floating gate NVM and the split gate 111 are isolated from each other by a first insulation layer 108 and a second insulation layer 109, and a drain 102 and a source 103 are positioned under their sides.

For the program operation of the device, hot electron injection is carried out. Through the injection, they jump the energy barrier of the tunnel oxide layer and are injected into the potential well formed in the floating gate, thereby a threshold voltage is increased. For the erase operation of the device, the electrons, which are stored in the potential well of the floating gate, are pulled out to the silicon substrate by FN(Fowler-Nordheim) tunneling mechanism, thereby the threshold voltage is decreased. For the read operation of the device, first, a middle voltage between the threshold voltages of the program state and the erase state is applied to the control gate. Next, a device state of either the program or the erase is known by detecting current due to the applied voltage. Taking advantage of split gate structure, the device doesn't additionally require a select gate, so that a chip area can be effectively reduced. Moreover, as the efficiency of the hot electron injection is likely to increase, a current for the program operation can be effectively reduced. In addition, this method prevents problems such as a drain turn-on and an over-erase.

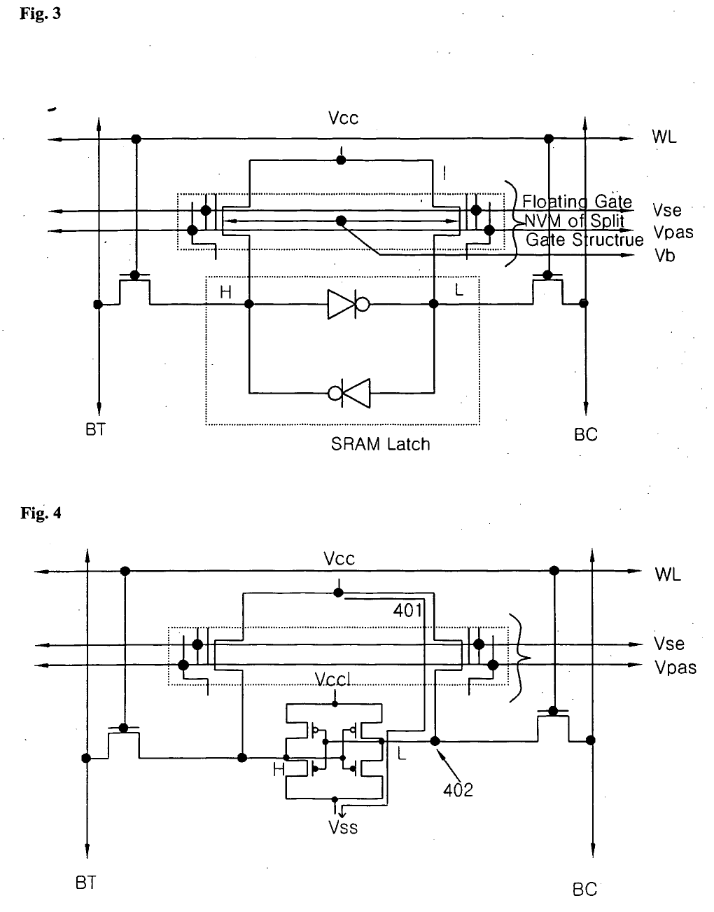

Referring to FIG. 3, unlike conventional nvSRAM, the nvSRAM according to the present invention substitutes a floating gate NVM device for an SONOS transistor, and a recall gate and a pass gate are not utilized. A unit cell of the nvSRAM according to the present invention comprises four NMOS transistors, two PMOS transistors and two floating gate NVM of split gate structure. In detail, the unit cell comprises two NMOS transistors and two PMOS transistors for an SRAM latch, two NMOS pass gates for reading and writing a HIGH condition and a LOW condition that are formed in the SRAM latch, two floating gate NVMs of split gate structure for storing the HIGH condition and the LOW condition which are stored in the SRAM latch when the power is off.

Unlike the conventional nvSRAM, the nvSRAM by this invention has a little bit different structure that a bias voltage is applied to a P-well region where the floating gate NVM device of split gate structure is positioned. Therefore, the P-well region of the floating gate NVM device of split gate structure should be isolated from the P-well region of the SRAM latch so that the bias voltage is applied to the P-well region of the floating gate NVM device and the P-well region of the SRAM latch has a well pick-up region.

Referring to FIG. 3, the nvSRAM using the floating gate NVM devices operates as follows. First, if the system is turned on, the data stored in the floating gate NVM devices, undergoing a recall mode and an erase mode one by one, is loaded in the SRAM latch and all the data stored in the floating gate NVM device is removed at the same time.

In the recall mode, once each bias of Vref[V], which means a reference voltage, 0[V], H[V] and +Vcc_rcl[V] is applied to a Vse, a Vb, a Vpas and a Vcc, the split gate becomes an ON condition. If the left floating gate NVM device and the right floating gate NVM device are in the erase state and the program state respectively, the left floating gate NVM device is in an ON condition. Therefore, a current is induced to flow from the Vcc and the left side of the SRAM latch lies in a HIGH condition and the right floating gate NVM device is in an OFF condition, so that there is no current flowing and the right side of the SRAM latch becomes a LOW condition. If the system is turned on in this way, the data stored in the floating gate NVM device is loaded into the SRAM latch, undergoing the recall mode. Preferably, the Vse voltage applied in the recall mode is equal to the Vref voltage that is generally set at a middle value between the threshold voltages of a programmed cell and an erased cell. The +Vcc_rcl[V] applied to the Vcc should be set with a safe voltage which is not too high to cause the program operation to take place during the recall mode.

No sooner has the recall operation been finished than the erase operation takes place. In the erase mode, if −Vers[V], +Vbers[V] or 0[V], 0[V] and a bias voltage of the floating gate is applied to the Vse, the Vb, the Vpas and the Vcc respectively for a certain time, the floating gate NVM device lies in a store mode due to the OFF condition of the split gate, so that most voltage applied to the Vse and the Vb is loaded to the ONO layer and the tunnel oxide layer of the floating gate NVM device. Therefore, the strong electric field applied to the tunnel oxide layer causes electrons accumulated in a potential well of the floating gate to be pulled out to the silicon substrate by the tunneling mechanism, so that the threshold voltage of the floating gate NVM device decreases. Since most floating gate NVM devices have the tunnel oxide layer with a thickness of about 100 Å to get a good retention characteristic, the speed of the erase operation by the tunneling mechanism is about 100[msec] which is too slow, so that the erase operation cannot be carried out when the system is turned off. Therefore, for the nvSRAM using the floating gate NVM device according to the present invention, when the system is turned on, two floating gate NVM devices connected to the SRAM latch are required to be erased through the erase operation after the recall operation is finished.

On the other band, when the system is turned off, it experiences the program mode during which the HIGH condition and the LOW condition in the SRAM latch are stored in the floating gate NVM device, and bias voltages of +Vpgm[V], 0[V], H[V] and +Vcc_pgm[V] are applied to the Vse, the Vb, the Vpas and the Vcc respectively. Under this bias condition, two floating gate NVM devices are all erased, so that they become an ON condition. Because the left side of the SRAM latch is in a HIGH condition, the Vgs of the left split gate becomes 0[V] that means an OFF condition, so that there is no current flowing. Therefore, the left floating gate NVM device keeps its erased state and the right side of the SRAM latch is in a LOW condition, so that the Vgs of the right split gate becomes a HIGH condition, thereby a current flows. The electrons forming the channel of a floating gate NVM are accelerated by the Vcc drain voltage and injected, i.e. hot-electron injected, into the floating gate NVM device, so that the threshold voltage of the right floating gate NVM device is increased. The program speed of the floating gate NVM device is about 100[μsec] which is very fast due to adoption of the hot electron injection. In the program mode, +Vpgm[V] may be applied to the Vse for a certain time(constant voltage mode) or the voltage applied to the Vse may be increased by a constant rate(step voltage mode).

Referring to FIG. 4, a static current pass which occurs in the program mode is illustrated. If the right side of the SRAM latch is in a LOW condition, a static current pass 401 occurs, which causes the electric potential at 402 to be changed. If the electric potential at 402 is as high as it can make the NMOS opposite to the SRAM latch turned on, there may be a possibility of an error that the electric potential of the right side abruptly changes from a LOW condition to a HIGH condition. Therefore, the electric potential is required not to be changed by the static current. However, since the electric potential at 402 cannot be exceed the difference(Vcc[V]−Vt_split[V]) between the Vcc and the threshold voltage of the split gate, as a solution, the threshold voltage of the split gate is necessary to be increased so that the electric potential at 402 doesn't exceed a predetermined value.

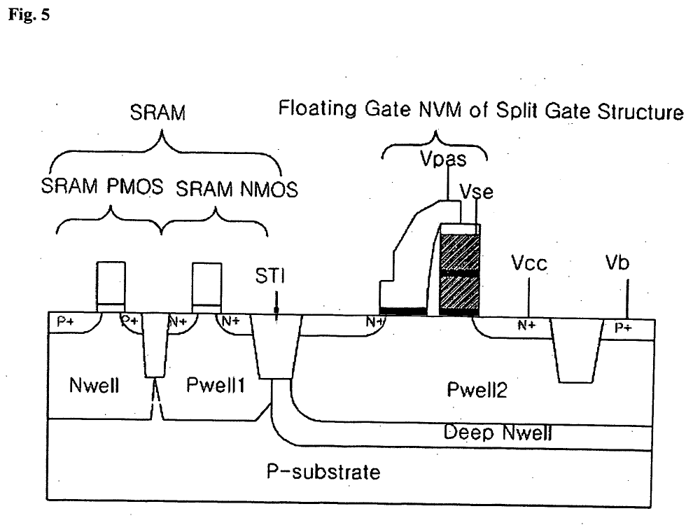

1. Referring to FIG. 5, a floating gate NVM device of split gate structure in accordance with the present invention is illustrated. Even if not described in detail, the same explanations apply to different conductive type. A PMOS transistor and an NMOS transistor for an SRAM are completed on an N-well region and a P-well 1 region respectively. The PMOS transistor includes the N-well in the semiconductor substrate, a gate on the N-well and P-type impurity regions under the sidewalls of the gate. The NMOS transistor includes the P-well 1 in the substrate neighboring a device isolation structure next to the N-well 1, a gate on the P-well 1 and N-type impurity regions under the sidewalls of the gate. A P-well 2 is positioned in the substrate neighboring a device isolation structure next to the P-well 1 and a deep N-well is positioned under the P-well 2. For a floating gate NVM device of split gate structure, it is placed on the P-well 2, N-type source and drain regions are positioned in the P-well 2, and a P-type impurity region is placed in the P-well 2. The P-type impurity region is isolated from the drain region of the floating gate NVM device of split gate structure by a device isolation structure. Furthermore, the deep N-well isolates the P-well 1 from the P-well 2. Vpas[V] and Vse[V] are applied to the split gate and the control gate of the floating gate NVM device of split gate structure respectively. Vcc[V] and Vb[V] are applied to the right drain of the floating gate NVM device and the P-well 2 region respectively.

Accordingly, the disclosed device presents a new type of the floating gate nvSRAM using the split gate and its advantages are as follows. First, the program speed is very fast, so that the desired capacitance, which is required to keep the system voltage constant for a certain time, may be reduced by a hundredfold. Second, since the device performs the program operation by means of hot electron injection, the efficiency of hot electron injection and the possibility that the electrons are trapped in the potential well of the floating gate NVM device are very high, so that a threshold voltage difference between the erased floating gate NVM device and the programmed one can be greatly increased over 5[V]. Third, since a thickness of the tunnel oxide layer according to the present invention is thicker than that according to the prior art, the floating gate NVM device using a split gate has a much better retention characteristic than that using a SONOS device. Fourth, in the nvSRAM using the SONOS device, as the time for the program lasts longer, even SONOS device that is not intended to be programmed experiences the program operation, so that the threshold voltage is increased. On the other hand, since this device according to the present invention cuts off a current by the pass gate, even if the time for the program lasts longer, the threshold voltage of the floating gate NVM device connected to “H” node of the SRAM does not increase. Fifth, a characteristic of the program operation is affected by a DWI characteristic for the nvSRAM using the SONOS device while not for the nvSRAM using the floating gate. Sixth, taking advantage of split gate structure, this device may accomplish a greatly diminished chip area.

It is noted that this patent claims priority from Korean Patent Application Serial Number 10-2003-0101079, which was filed on Dec. 31, 2003, and is hereby incorporated by reference in its entirety.

The foregoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

1. A semiconductor device comprising:
two NMOS transistors and two PMOS transistors for an SRAM latch;
two NMOS pass gates for reading and writing a HIGH condition and a LOW condition that are formed in the SRAM latch; and
two floating gate NVM devices of split gate structure for storing the HIGH condition and the LOW condition that are stored in the SRAM latch when the power is off.

2. A semiconductor device as defined by claim 1, wherein a bias voltage is applied to the well region where the floating gate NVM device of split gate structure is positioned.

3. A semiconductor device as defined by claim 1, wherein the well regions on which the SRAM latch and the floating gate NVM device of split gate structure are positioned are isolated from each other by a deep well of the conductive type opposite to them.

4. A semiconductor device as defined by claim 1, wherein the floating gate NVM device of split gate structure comprises a stacked structure having a tunnel oxide layer, a floating gate, an ONO layer and a control gate, a split gate on the sidewalls of the stacked structure, an insulation layer between the stacked structure and the split gate, and drain and source regions located under the sidewalls of the stacked structure and the split gate.

5. A semiconductor device comprising:
a semiconductor substrate of the first conductive type;
a MOS transistor of the first conductive type including a first well of the second conductive type in the semiconductor substrate a gate on the first well of the second conductive type and impurity regions of the first conductive type under the sidewalls of the gate;
a MOS transistor of the second conductive type including a first well of the first conductive type in the substrate neighboring a device isolation structure next to the first well of the second conductive type, a gate on the first well of the first conductive type and impurity regions of the second conductive type under the sidewalls of the gate;
a second well of the first conductive type in the substrate neighboring a device isolation structure next to the first well of the first conductive type;
a second well of the second conductive type under the second well of the first conductive type;
a floating gate NVM device of split gate structure on the second well of the first conductive type, and source and drain regions of the second conductive type in the second well of the first conductive type; and
an impurity region of the first conductive type in the second well of the first conductive type.

6. A semiconductor device as defined by claim 5, wherein the impurity region of the first conductive type is isolated from the drain region of the floating gate NVM device of split gate structure by a device isolation structure.

7. A semiconductor device as defined by claim 5, wherein the second well of the second conductive type isolates the first well of the first conductive type from the second well of the first conductive type.
